(19) United States
(12) Patent Application Publication
(10) Pub. No.: US 2005/0098864 A1
(43) Pub. Date: May 12, 2005

(54) Jig device for packaging an image sensor

(76) Inventor: Reg Yang, Hsinchu Hsien (TW)

Correspondence Address: PRO-TECHTOR INTERNATIONAL, 20775 Norada Court, Saratoga, CA, 95070-3018, US

(21) Appl. No.: 10/705,375

(22) Filed: Nov. 10, 2003

(51) Int. Cl. H01L 23/02

(52) U.S. Cl. 257/678

(57) ABSTRACT

A carrier mechanism for an image sensor package, the carrier is for fixing the transparent layer of the image sensor. The carrier mechanism includes a substrate and plural positioned posts. The substrate has an upper surface, a lower surface, and plural penetrated slots through the upper surface to the lower surface of the substrate. At the periphery of the each penetrated slot of the substrate is formed with plural fixing regions, then the transparent layer is not contact with the upper surface of the substrate. The plurality of positioned post is fixed at the fixing region of the substrate to fix the periphery of the transparent layer.

### BACKGROUND OF THE INVENTION

1. Field of the Invention

The invention relates to a carrier mechanism for an image sensor package, and in particular to fix a transparent layer for an image sensor package, so may be decrease the damage of the transparent layer, so as to increase the production yield.

2. Description of the Related Art

Referring to FIG. 1, a conventional image sensor includes a substrate 10, a frame layer 18, a photosensitive chip 26, a plurality of wires 28, and a transparent layer 34. The substrate 10 has a first surface 12 on which a plurality of signal input terminals 15 is formed, and a second surface 14 on which a plurality of signal output terminals 16 is formed. The frame layer 18 has an upper surface 20 and a lower surface 22 adhered to the first surface 12 of the substrate 10 to form a chamber 24 together with the substrate 10. The photosensitive chip 26 is arranged within the chamber 24 and is mounted to the first surface 12 of the substrate 10. Each wire 28 has a first terminal 30 and a second terminal 32. The first terminals 30 are electrically connected to the photosensitive chip 26, and the second terminals 32 are electrically connected to the signal input terminals 15 of the substrate 10. The transparent layer 34 is adhered to the upper surface 20 of the frame layer 18.

In order to finish the above-mentioned package processes, the transparent layer 34 10 has to be efficiently cleaned, so as to decrease the particle, and positioned transparent layer 34 to a carrier for operator to take that.

Please refer to FIG. 2, is a traditional carrier mechanism for an image sensor package includes a substrate 40, which is formed with plural penetrated slots 42, each which is formed with a frame 44. Please refer to FIG. 3, is a cross-sectional showing a carrier for image sensor package, while the transparent layer 34 is cleaned after, is positioned to the penetrated slot 42, and located on the frame 44.

However, the conventional carrier mechanism for an image sensor package has following drawbacks.
1. Since the surface of the transparent layer 34 is contacted the surface of the frame, so the surface of the transparent layer 34 is easily damage. Thus, the manufacturing yield is decrease.

### SUMMARY OF THE INVENTION

An objective of the invention is to provide a carrier mechanism for an image sensor package, wherein the processes for packaging an image sensor may be efficiently cleaned, so as to increase the production yield.

To achieve the above-mentioned object, the invention includes a substrate and plural positioned post. The substrate is formed with an upper surface, a lower surface, and plural penetrated slots through the upper surface to the lower surface of the substrate. At the periphery of the each penetrated slot of the substrate is formed with plural fixing regions, then the transparent layer is not contact with the upper surface of the substrate. The positioned post is fixed at the fixing region of the substrate to fix the periphery of the transparent layer.

### BRIEF DESCRIPTION OF THE DRAWINGS

FIG. 1 is a schematic illustration view showing a conventional image sensor package.

FIG. 2 is a cross-sectional view showing a conventional carrier mechanism for an image sensor package.

FIG. 3 is a schematic illustration showing a carrier mechanism for an image sensor package of the present invention.

FIG. 4 is a top view showing a carrier mechanism for an image sensor package of the present invention.

FIG. 5 is a schematic illustration showing a carrier mechanism for an image sensor package of the present invention.

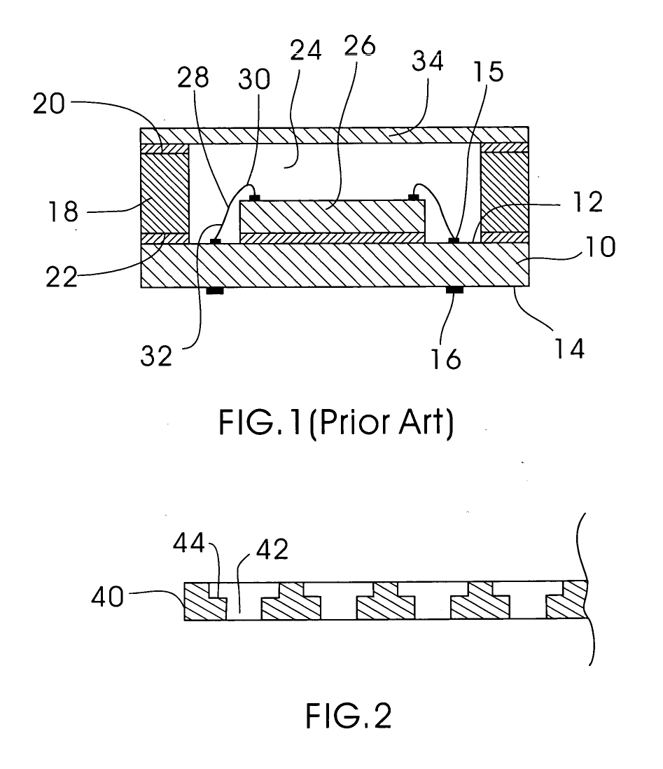

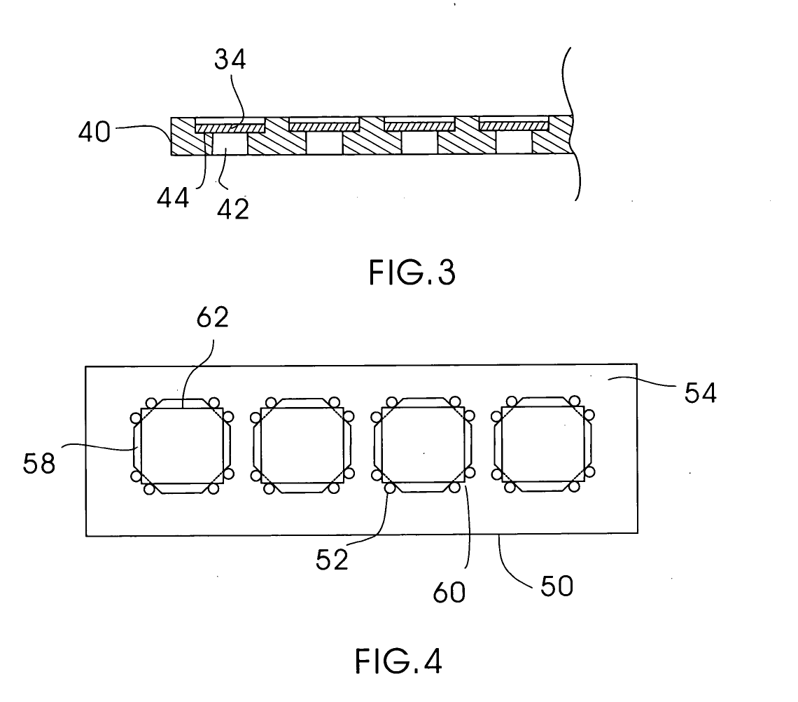

### DETAILED DESCRIPTION OF THE INVENTION

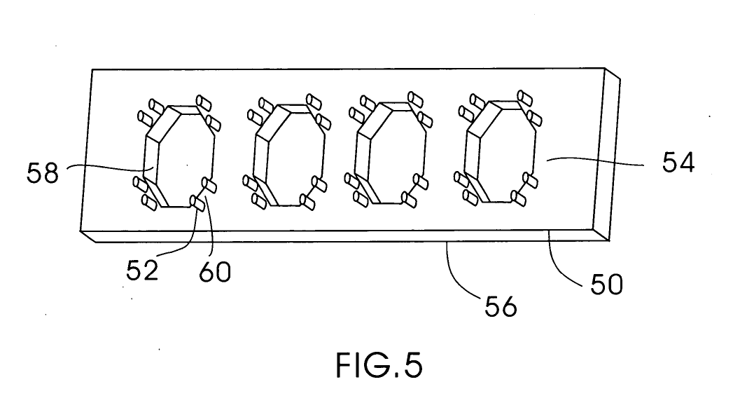

Please refer to FIG. 4 and FIG. 5. A carrier mechanism for an image sensor of the present invention includes a substrate 50 and plural positioned posts 52.

The substrate 50 is formed with an upper surface 54, a lower surface 56, and plural penetrated slots 56 through the upper surface 54 to the lower surface 56 of the substrate 50. In the embodiment, the penetrated slot 56 is a shaped of octagon, at the periphery of the each penetrated slot 58 of the substrate 50 is formed with plural fixing regions 60, then the transparent layer 62 is not contact with the upper surface 54 of the substrate 52.

Plural positioned post 52, each which is fixed at the fixing region 60 of the substrate. In the embodiment, each fixing region 60 has two positioned posts 50 to fix the periphery of the transparent layer 62. And the plural positioned posts 52 are integrated formed with the substrate 50.

The transparent layer 62 is arranged at the top of the penetrated slot 58 of the substrate 50, so each angle of the transparent layer 62 is located between positioned posts 52 located at the fixing region 60. Therefore the transparent layer 62 is fixed and the surface of the transparent layer 62 is not contact with the substrate 50, so that the surface of the transparent layer 62 can not damage to increase the production yield.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A carrier mechanism for an image sensor package, the carrier is for fixing the transparent layer of the image sensor, the carrier mechanism comprising:
a substrate formed with an upper surface, a lower surface, and plural penetrated slots through the upper surface to the lower surface of the substrate, at the periphery of the each penetrated slot of the substrate being formed with plural fixing regions, then the transparent layer is not contact with the upper surface of the substrate; and
a plurality of positioned post being fixed at the fixing region of the substrate to fix the periphery of the transparent layer.

2. The carrier mechanism according to claim 1, wherein plural penetrated slots are a shaped of an octagon, then the fixing regions is located at the corresponding to angle of the octagon.

3. The carrier mechanism according to claim 1, wherein the plural positioned posts are integrated formed with the substrate.

4. The carrier mechanism according to claim 1, wherein the each fixing region has tow fixed post.
